(19) United States
(12) Patent Application Publication
(10) Pub. No.: US 2010/0176446 A1
(43) Pub. Date: Jul. 15, 2010

(54) MOSFET with source contact in trench and integrated schottky diode

(75) Inventor: Fu-Yuan Hsieh, Kaohsiung (TW)

Correspondence Address: BACON & THOMAS, PLLC, 625 SLATERS LANE, FOURTH FLOOR, ALEXANDRIA, VA, 22314-1176, US

(73) Assignee: FORCE MOS TECHNOLOGY CO. LTD., Kaohsiung (TW)

(21) Appl. No.: 12/318,929

(22) Filed: Jan. 13, 2009

(51) Int. Cl. H01L 29/78

(52) U.S. Cl. 257/334; 257/E29.262

(57) ABSTRACT

A trench semiconductor power device with integrated Schottky diode is disclosed. P+ regions and n+ source regions are alternately arranged in mesa and on top of trench sidewall along stripe source-body contact area between two adjacent trenches. By employing this structure, cell density increased remarkably without increasing contact resistance because top portion of gate trench sidewall is provided as source-body contact area.

### FIELD OF THE INVENTION

This invention relates generally to the cell structure and device configuration of semiconductor devices. More particularly, this invention relates to an improved cell configuration to manufacture trench semiconductor power device with source contact in trench and integrated Schottky diode.

### BACKGROUND OF THE INVENTION

It is known that channel packing density (Channel width per unit area) and cell density play important roles in the aspect of improving the Performance/Area-cost ratio of trench semiconductor power device. Therefore, many kinds of trench semiconductor power devices were disclosed in prior arts trying to achieve higher channel packing density and cell density.

In U.S. Pat. No. 6,737,704, a trench MOSFET cell with source-body contact on inner circumferential surface was disclosed, as shown in FIG. 1. This cell is formed on a heavily doped substrate 100 of a first semiconductor doping type (e.g., N type) on which a lightly doped epitaxial layer 102 of the same first semiconductor doping type is grown. At least one trench is etched inside said epitaxial layer 102 and filled with doped poly within trenches to serve as at least one trench gate 104 over the gate oxide layer 108. Beside said trench gate 104, there is a P-body region 112 introduced by Ion Implantation, A plurality of n+ source regions 114 are implanted adjacent to the upper portion of gate trenches sidewalls in said P-body region 112, and a plurality of P+ regions 113 are formed surrounding said n+ source region 114. A layer of metal 118 are directly filled into upper portion of gate trench to contact n+ source region with source metal, and also contact n+ source with body region laterally.

What should be noticed is that, the body contact region 113 locating between two adjacent trenches occupies a large amount of mesa area, which limits the increasing of cell density. Besides that, FIG. 3 and FIG. 4 lead to the conclusion that when mesa width is smaller than trench width, stripe cell design is better than closed cell due to higher channel packing density resulting in low on-resistance Rds between drain and source. Since structure of the trench MOSFET in prior art is closed cell, the lower channel packing density leads to a high on-resistance Rds.

In U.S. Pat. No. 7,402,863, another trench MOSFET cell with source-body contact on inner surface is shown in FIG. 2. Comparing to FIG. 1, in this structure, an additional Ti/TiN 111′ is added before the deposition of metal layer 118′ as interconnection metal layer, however, the requirement of a large area also exists.

Accordingly, it would be desirable to provide trench semiconductor power device with source contact in trench to reduce device area and to improve the Performance/Area-cost ratio

### SUMMARY OF THE INVENTION

It is therefore an object of the present invention to provide new and improved trench semiconductor power device to solve the problems discussed above.

One aspect of the present invention is that, a trench semiconductor power device with improved source contact in trench as shown in FIGS. 5, 6 and 7 is invented to reduce the area requirement. p+ body contact regions and n+ source regions are alternately arranged in mesa and on top of trench sidewall along stripe source-body contact area between two adjacent trenches to save P+space for device die size shrinkage. The ratio of n+/p+ ranges from 1:1 to 20:1. The device cell pitch can be significantly shrunk from 1.0 um down to 0.4 um and cell density thus increased from 700 M/in² to 2 G/in² without increasing contact resistance because top portion of gate trench sidewall is provided as source-body contact area.

Another aspect of the present invention as shown in FIGS. 8 and 9 is that, a trench semiconductor power device with source contact in trench and integrated Schottky diode is invented to integrated trench Schottky diode with the MOSFET with less area requirement because Schottky diode is not only formed on top surface of epitaxial layer but also on top portion of Schottky contact trench sidewall.

Briefly, in a preferred embodiment of trench MOSFET as shown in FIGS. 5 and 6, the present invention disclosed a trench semiconductor power device formed on a heavily doped substrate of a first semiconductor doping type (e.g., N type). Onto said substrate, a lightly doped epitaxial layer of a same first semiconductor doping type is grown, and a plurality of trenches are etched wherein, doped poly is filled partially into bottoms of said trenches to serve as trench gates over a gate oxide layer along the inner surface of said gate trenches. P-body regions are extending between each gate trenches. P+ body contact regions and n+ source regions are alternately arranged in mesa and on top of said gate trench sidewall along stripe source-body contact area between two adjacent gate trenches. A layer of oxide is formed on the top surface of said doped poly in gate trenches and a layer of Ti/TiN, Co/TiN or Ta/TiN serving as an interconnection metal layer is deposited on the top surface of the whole device. Front metal are directly filled into upper portion of gate trenches onto said interconnection metal layer to contact n+ source region and P+ body region laterally and vertically.

Briefly, in another preferred embodiment of device structure as shown in FIG. 7, wherein the trench MOSFET structure disclosed is the same as the structure mentioned in the first embodiment except that tungsten is filled into upper portion of gate trenches to serve as trench metal plug. Onto a layer of Ti or Ti/TiN, Al alloys or copper as front metal covers the top surface of whole structure contacts source and body laterally.

Briefly, in another preferred embodiment of device structure as shown in FIG. 8, wherein the trench MOSFET structure disclosed is the same as the structure mentioned in the first embodiment except that there is an monolithically integrated Schottky diode formed on top surface of epitaxial layer and top portion of trench sidewall.

Briefly, in another preferred embodiment of device structure as shown in FIG. 9, wherein the trench MOSFET structure disclosed is the same as the structure mentioned in the second embodiment except that there is an monolithically integrated Schottky diode formed on top surface of epitaxial layer and top portion of trench sidewall.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a trench MOSFET of prior art.

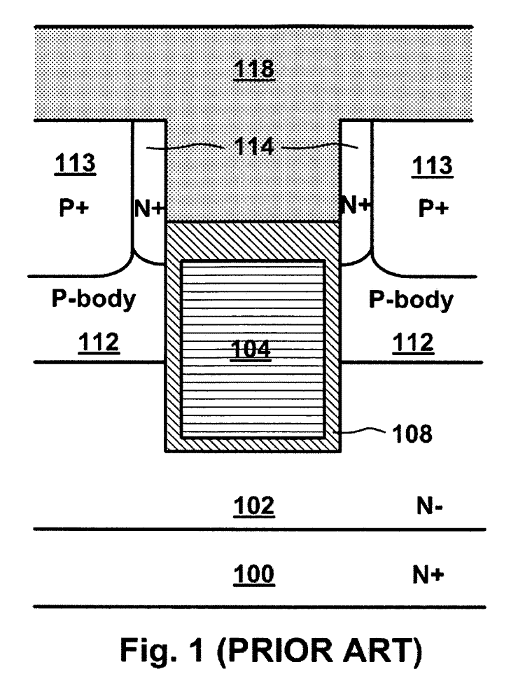

FIG. 2 is a side cross-sectional view of a trench MOSFET of another prior art.

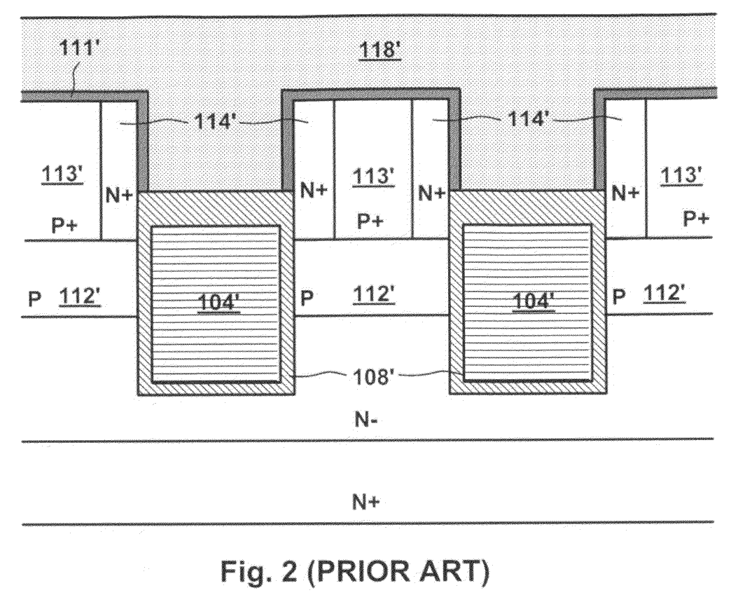

FIG. 3 is channel packing density calculation method of closed cell and stripe cell.

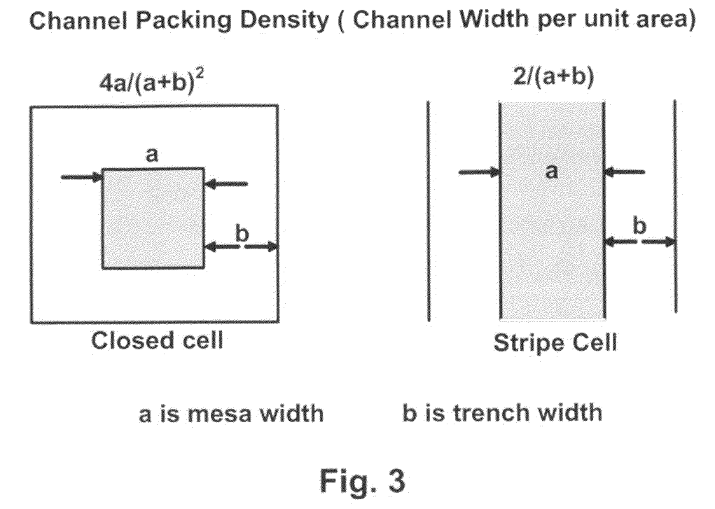

FIG. 4 is the channel packing density comparison of closed cell and stripe cell.

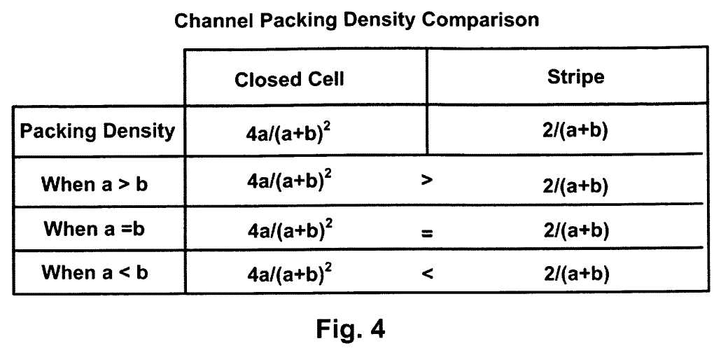

FIG. 5 is a three-dimensional view of a trench semiconductor power device of a preferred embodiment of the present invention.

FIG. 6 is a top view of a trench semiconductor power device shown in FIG. 5.

FIG. 7 is a three-dimensional view of a trench semiconductor power device of another preferred embodiment of the present invention.

FIG. 8 is a side cross-sectional view of a trench semiconductor power device with integrated Schottky diode of another preferred embodiment of the present invention.

FIG. 9 is a side cross-sectional view of a trench semiconductor power device with integrated Schottky diode of another preferred embodiment of the present invention.

### DETAILED DESCRIPTION OF THE EMBODIMENTS

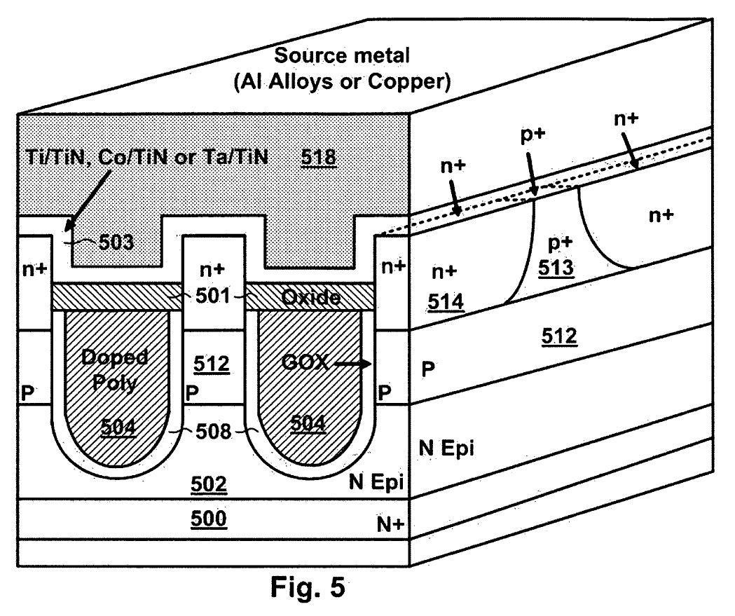

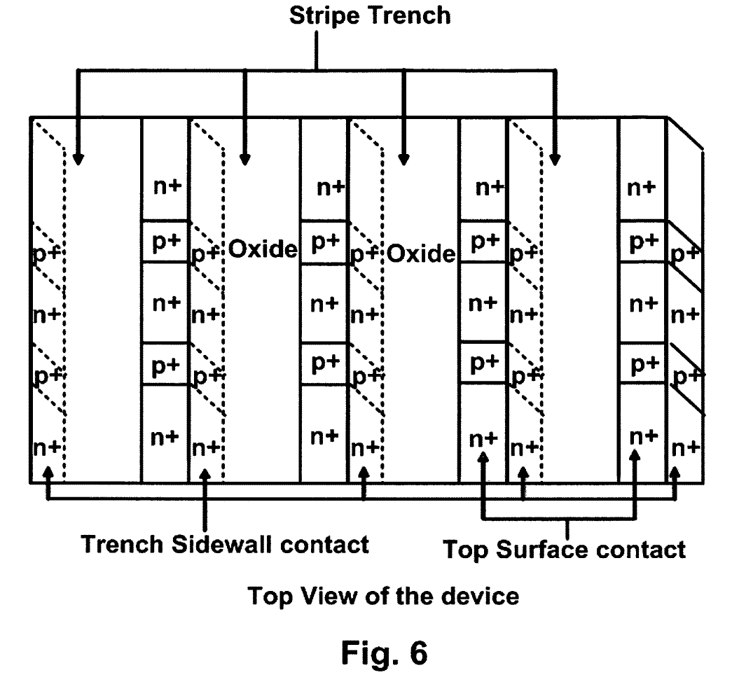

In FIG. 5, the present invention disclosed a trench semiconductor power device formed on a heavily doped substrate 500 of a first semiconductor doping type (e.g., N type). Onto said substrate 500, grow a lightly doped epitaxial layer 502 of a same first semiconductor doping type, and a plurality of trenches are etched wherein, doped poly is filled partially into bottom of said trenches to serve as trench gates 504 over a gate oxide layer 508 along the inner surface of said gate trenches. P-body regions 512 are extending between each gate trenches. P+ body contact regions 513 and n+ source regions 514 are alternately arranged in mesa and on top of said gate trench sidewall along stripe source-body contact area between two adjacent gate trenches. An isolation layer of oxide 501 is formed on the top surface of said doped poly in gate trenches and a layer of Ti/TiN, Co/TiN or Ta/TiN 503 serving as an interconnection metal layer is deposited on the top surface of the device. Al alloys or copper as front metal 518 are directly filled into upper portion of gate trenches onto said interconnection metal layer 503 to contact n+ source region 514 and p+ body contact region 513 laterally and vertically. FIG. 6 is the top view of the trench semiconductor power device which shows that both of the source contact in n+ region and the body contact in p+ body contact region contain trench sidewall contact and top surface contact which leads to a reduction of area requirement. The n+ area:p+ area ratio ranges from 1:1 to 20:1

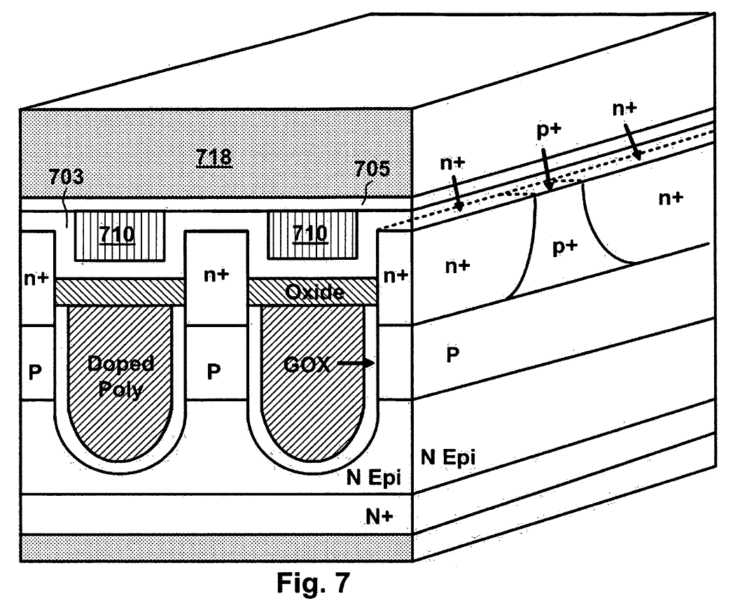

In FIG. 7, the shown device has the same trench MOSFET structure as that in FIG. 5 except that a layer of silicide 703 instead of a layer of Ti/TiN, Co/TiN or Ta/TiN is deposited on the top surface of the device. Tungsten is filled into upper portion of gate trenches serving as trench metal plug 710. Onto a layer of Ti or Ti/TiN 705, front metal 718 covering the top surface of whole structure contacts source and body laterally.

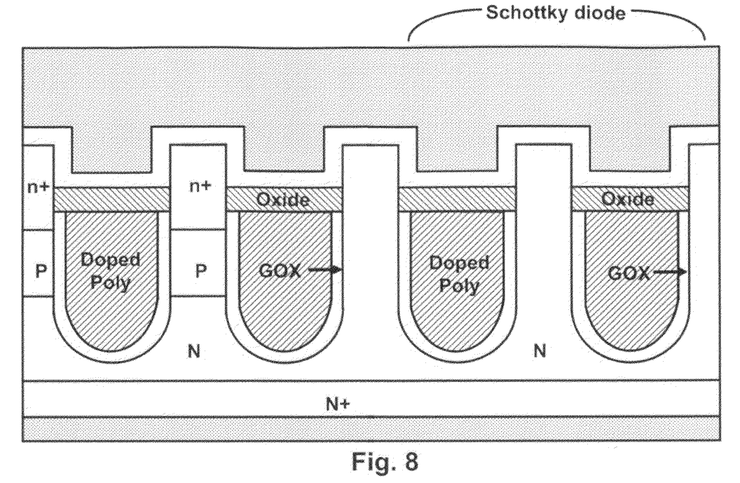

In FIG. 8, the shown device has the same trench MOSFET structure as that in FIG. 5 except that there is a monolithically integrated Schottky diode formed on top surface of epitaxial layer and top portion of trench sidewall.

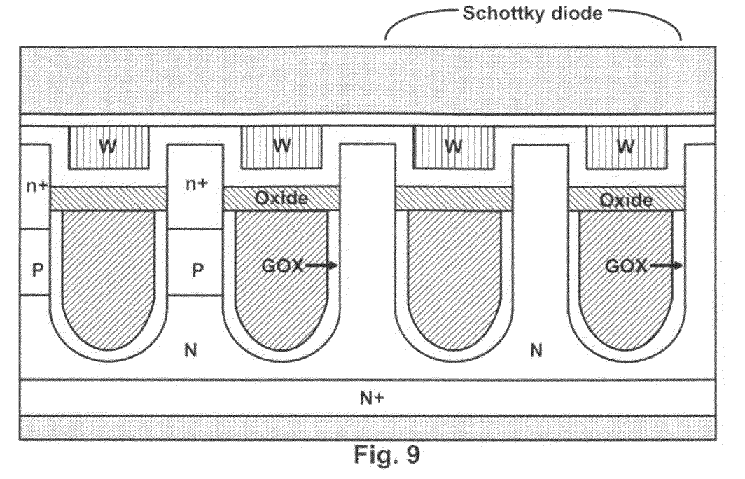

In FIG. 9, the shown device has the same trench MOSFET structure as that in FIG. 7 except that there is a monolithically integrated Schottky diode formed on top surface of epitaxial layer and top portion of trench sidewall.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A vertical semiconductor power MOS device compromising a plurality of semiconductor power cells with each cell comprising a plurality of trench gates surrounded by a plurality of source regions above a plurality of body regions above a drain region disposed on a bottom surface of a substrate, wherein said trench MOSFET further comprising:
a substrate made of first conductivity type semiconductor;
an epitaxial layer made of the first conductivity type semiconductor over the substrate and having a lower doping concentration than the substrate;
a plurality of body regions made of second conductivity type semiconductor inside the first epitaxial layer as body regions of the trench MOSFET;
a plurality of gate trenches formed to reach the epitaxial layer;
a plurality of heavily doped source regions made of first conductivity type semiconductor inside the body regions as source regions of the trench MOSFET and having a higher doping concentration than the epitaxial layer;
a plurality of heavily doped body contact regions made of second conductivity type semiconductor and said source regions alternately arranged inside body regions along stripe source-body contact area between two adjacent trenches;
a gate oxide layer formed to wrap the bottom of each trench gate and lower portion of trench sidewall;
a plurality of doped poly filling partially within said lower portion of gate trenches;
an isolation oxide layer covering top surface of doped poly and gate oxide in said gate trenches separating trench gate from source metal connection;
a front source metal layer connected to both source and body contact regions laterally on top of the epitaxial layer and vertically on top portion of trench sidewall.

2. The trench power semiconductor device of claim 1, wherein heavily doped source region is N type conductivity and heavily doped body contact region is P type conductivity for N-channel Trench MOSFET.

3. The trench power semiconductor device of claim 1, wherein said heavily doped source region is P type conductivity and heavily doped body contact region is N type conductivity for P-channel Trench MOSFET.

4. The trench power semiconductor device of claim 1, wherein said gate trenches are partially filled with polysilicon therein exposing upper trench sidewalls adjacent to said source regions.

5. The trench power semiconductor device of claim 1, wherein said trench gates are padded with a gate oxide layer on the lower portion of trench sidewalls and the bottom surface;

6. The trench power semiconductor device of claim 1, wherein said contact oxide layer fills a top portion of the trench gate with a portion of the trench sidewalls exposed to the source regions for contacts.

7. The trench power semiconductor device of claim 1, wherein said front metal is Ti/TiN/Al alloys or Ta/TiN/Cu filled in the upper portion of gate trenches as source terminal.

8. The trench power semiconductor device of claim 1, onto a layer of Ti or Ti/TiN, said front metal composed of Al alloys or copper connected with W metal plug filled in upper portion of gate trenches.

9. A monolithically trench power semiconductor structure combining trench MOSFET and Trench Schottky diode, wherein said trench MOSFET further comprising:
a substrate made of first conductivity type semiconductor as drain terminal;
an epitaxial layer made of the first conductivity type semiconductor over the substrate and having a lower doping concentration than the substrate;
a plurality of body regions made of second conductivity type semiconductor inside the first epitaxial layer as body regions of the trench MOSFET;
a plurality of gate trenches formed to reach the epitaxial layer;
a plurality of heavily doped source regions made of first conductivity type semiconductor inside the body regions as source regions of the trench MOSFET and having a higher doping concentration than the epitaxial layer;
a plurality of heavily doped regions made of second conductivity type semiconductor and said source regions alternately arranged inside body regions along stripe source-body contact area between two adjacent trenches;
a gate oxide layer formed to wrap the bottom of each trench gate and lower portion of trench sidewall;
a plurality of doped poly filling partially within said lower portion of gate trenches;
an isolation oxide layer covering top surface of doped poly and gate oxide in said gate trenches;
a front metal layer connected to both source and body contact regions laterally on top of the epitaxial layer and vertically on top portion of trench sidewall as source terminal of said trench MOSFET;
wherein said the trench Schottky diode having a barrier layer formed on top of the epitaxial layer between two adjacent trench gates and top portion of trench sidewall, connected to the front metal as anode terminal;

10. The monolithically trench power semiconductor device of claim 9, wherein said gate trenches are partially filled with polysilicon therein exposing upper trench sidewalls adjacent to said source regions in said trench MOSFET and anode regions in said Schottky diode.

11. The monolithically trench power semiconductor device of claim 9, wherein said trench gates are padded with a gate oxide layer on the lower portion of trench sidewalls and the bottom surface;

12. The monolithically trench power semiconductor device of claim 9, wherein said isolation oxide layer fills a top portion of the trench gate with a portion of the trench sidewalls exposed to the source regions in said trench MOSFET and anode regions in said trench Schottky diode for contacts.

13. The monolithically trench power semiconductor device of claim 9, wherein said front metal is Ti/TiN/Al alloys or Ta/TiN/Cu filled in the upper portion of gate trenches as source terminal for said trench MOSFET and anode terminal for said trench Schottky diode.

14. The monolithically trench power semiconductor device of claim 9, onto a layer of Ti or Ti/TiN, said front metal composed of Al alloys or copper connected with W metal plug filled in upper portion of gate trenches.
